(19) United States
(12) Patent Application Publication
(10) Pub. No.: US 2014/0284665 A1
(43) Pub. Date: Sep. 25, 2014

(54) SOLID-STATE IMAGING DEVICE, PRODUCTION METHOD THEREOF, AND ELECTRONIC APPARATUS

(71) Applicant: Sony Corporation, Tokyo (JP)

(72) Inventor: Takashi Abe, Kanagawa (JP)

(73) Assignee: Sony Corporation, Tokyo (JP)

(21) Appl. No.: 14/209,871

(22) Filed: Mar. 13, 2014

(30) Foreign Application Priority Data
Mar. 25, 2013 (JP) 2013-062019

(51) Int. Cl. H01L 27/146

(52) U.S. Cl. CPC H01L 27/146; H01L 27/14683
USPC 257/239; 438/73

(57) ABSTRACT

There is provided a solid-state imaging device including a pixel array unit in which pixels are arrayed in a two-dimensional manner, each of the pixels including a plurality of photoelectric conversion elements and a floating diffusion configured to accumulate an electric charge from the plurality of photoelectric conversion elements, wherein the floating diffusion is shared by at least two or more of the photoelectric conversion elements, and wherein one or more of the plurality of photoelectric conversion elements include a transfer gate configured to transfer an electric charge between the photoelectric conversion elements that are adjacent.

### CROSS REFERENCE TO RELATED APPLICATIONS

This application claims the benefit of Japanese Priority Patent Application JP 2013-062019 filed Mar. 25, 2013, the entire contents of which are incorporated herein by reference.

### BACKGROUND

The present technology relates to a solid-state imaging device, a production method thereof, and an electronic apparatus, particularly, to a solid-state imaging device, a production method thereof, and an electronic apparatus that make it possible to form a divided pixel with a higher flexibility.

In related art, there has been a solid-state imaging device that includes a plurality of pixels and in which the photoelectric conversion elements of some or all of the pixels are plurally divided.

For example, there has been proposed a solid-state imaging device in which the photoelectric conversion element of one pixel is divided into four in a 2×2 manner and color filters with the same color are provided respectively (see JP 2000-152260A).

In such a configuration, by varying the accumulation time for each photoelectric conversion element and synthesizing the obtained signals, it is possible to obtain an image with a broad dynamic range. Furthermore, the reading of the electric charge becomes easy compared to a non-divided photoelectric conversion element, and the PN junction area in the lateral cross-section direction increases so that more saturation signal amount can be obtained.

### SUMMARY

However, in the pixel with the plurally-divided photoelectric conversion element (also referred to as “the divided pixel,” hereinafter), it has been difficult to unlimitedly increase the division number of the photoelectric conversion element.

For example, when the photoelectric conversion element is divided into four in a 2×2 manner, a floating diffusion (referred to as an FD, hereinafter) is disposed at the center on the plane, and a transfer gate is provided at the interval with each photoelectric conversion element.

Alternatively, when the photoelectric conversion element is divided into nine in a 3×3 manner, the FD is disposed at the photoelectric conversion element position that is the center on the plane, and one pixel includes eight photoelectric conversion elements. However, the positional relation (distance) to the FD is different for each photoelectric conversion element, resulting in a variation in electric charge transfer characteristic.

In addition, when the photoelectric conversion element is divided into sixteen in a 4×4 manner, the FD is disposed at the center on the plane. However, it is difficult to design such that the transfer gates are provided between the FD and the twelve photoelectric conversion elements that are disposed on the outer side.

The present technology has been made in view of such a circumstance, and makes it possible to form a divided pixel with a higher flexibility.

According to an embodiment of the present technology, there is provided a solid-state imaging device including a pixel array unit in which pixels are arrayed in a two-dimensional manner, each of the pixels including a plurality of photoelectric conversion elements and a floating diffusion configured to accumulate an electric charge from the plurality of photoelectric conversion elements. The floating diffusion is shared by at least two or more of the photoelectric conversion elements. One or more of the plurality of photoelectric conversion elements include a transfer gate configured to transfer an electric charge between the photoelectric conversion elements that are adjacent.

Of the plurality of photoelectric conversion elements, the photoelectric conversion elements except the photoelectric conversion elements sharing the floating diffusion may include the transfer gate, and the transfer gate may be formed on a separation region that is formed between the photoelectric conversion elements that are adjacent.

An impurity concentration of the separation region may decrease as a cross-section height thereof increases.

At least part of the transfer gate may be implanted in a trench formed in the separation region.

An impurity concentration of the photoelectric conversion element may increase as a distance between the photoelectric conversion element and the floating diffusion shortens.

The transfer gate may be formed for each photoelectric conversion element group, the photoelectric conversion element group being an aggregate of the photoelectric conversion elements.

A drive signal driving the transfer gate may be supplied to the transfer gate for each photoelectric conversion element group depending on an imaging mode.

A drive signal driving the transfer gate may be supplied to the transfer gate for each photoelectric conversion element group depending on an imaging environment.

According to an embodiment of the present technology, there is provided a production method of a solid-state imaging device including a pixel array unit in which pixels are arrayed in a two-dimensional manner, each of the pixels including a plurality of photoelectric conversion elements and a floating diffusion configured to accumulate an electric charge from the plurality of photoelectric conversion elements, the production method including forming the floating diffusion shared by at least two or more of the photoelectric conversion elements, and forming a transfer gate configured to transfer an electric charge between the photoelectric conversion elements that are adjacent, for one or more of the plurality of photoelectric conversion elements.

According to an embodiment of the present technology, there is provided an electronic apparatus including a solid-state imaging device including a pixel array unit in which pixels are arrayed in a two-dimensional manner, each of the pixels including a plurality of photoelectric conversion elements and a floating diffusion configured to accumulate an electric charge from the plurality of photoelectric conversion elements. The floating diffusion is shared by at least two or more of the photoelectric conversion elements. One or more of the plurality of photoelectric conversion elements include a transfer gate configured to transfer an electric charge between the photoelectric conversion elements that are adjacent

In an embodiment of the present technology, the floating diffusion is shared by at least two or more of the photoelectric conversion elements, and the transfer gate to transfer an electric charge between the photoelectric conversion elements that are adjacent is provided in some of the plurality of the photoelectric conversion elements.

According to an embodiment of the present technology, it is possible to form a divided pixel with a higher flexibility.

### BRIEF DESCRIPTION OF THE DRAWINGS

FIG. 1 is a block diagram showing an exemplary configuration of an embodiment of a solid-state imaging device to which the present technology is applied;

FIG. 2 is a block diagram showing an exemplary configuration of pixels of a pixel array unit and its peripheral circuits;

FIG. 3 is a timing chart showing an example of a drive timing of the pixel;

FIG. 4 is a diagram showing an example of the planar and cross-sectional structures of the pixel;

FIG. 5 is a diagram showing a modification of the cross-sectional structure of the pixel;

FIG. 6 is a diagram showing a modification of the cross-sectional structure of the pixel;

FIG. 7 is a diagram showing a modification of the planar and cross-sectional structures of the pixel;

FIG. 8 is a diagram showing a modification of the planar structure of the pixel;

FIG. 9 is a timing chart showing an example of a drive timing of the pixel in FIG. 8;

FIG. 10 is a diagram showing a modification of the planar structure of the pixel;

FIG. 11 is a timing chart showing an example of a drive timing of the pixel in FIG. 10;

FIG. 12 is a flowchart for explaining a formation process of the pixel;

FIG. 13 is a diagram showing a stage of formation of the pixel;

FIG. 14 is a diagram showing a stage of formation of the pixel;

FIG. 15 is a diagram showing a stage of formation of the pixel;

FIG. 16 is a diagram showing a stage of formation of the pixel;

FIG. 17 is a diagram showing a stage of formation of the pixel;

FIG. 18 is a diagram showing a stage of formation of the pixel;

FIG. 19 is a diagram showing an alternative example of the planar structure of the pixel;

FIG. 20 is a diagram showing a further alternative example of the planar structure of the pixel; and

FIG. 21 is a block diagram showing an exemplary configuration of an embodiment of an electronic apparatus to which the present technology is applied.

### DETAILED DESCRIPTION OF THE EMBODIMENT(S)

Hereinafter, embodiments of the present technology will be described with reference to the drawings.

### [An Exemplary Configuration of a Solid-State Imaging Device]

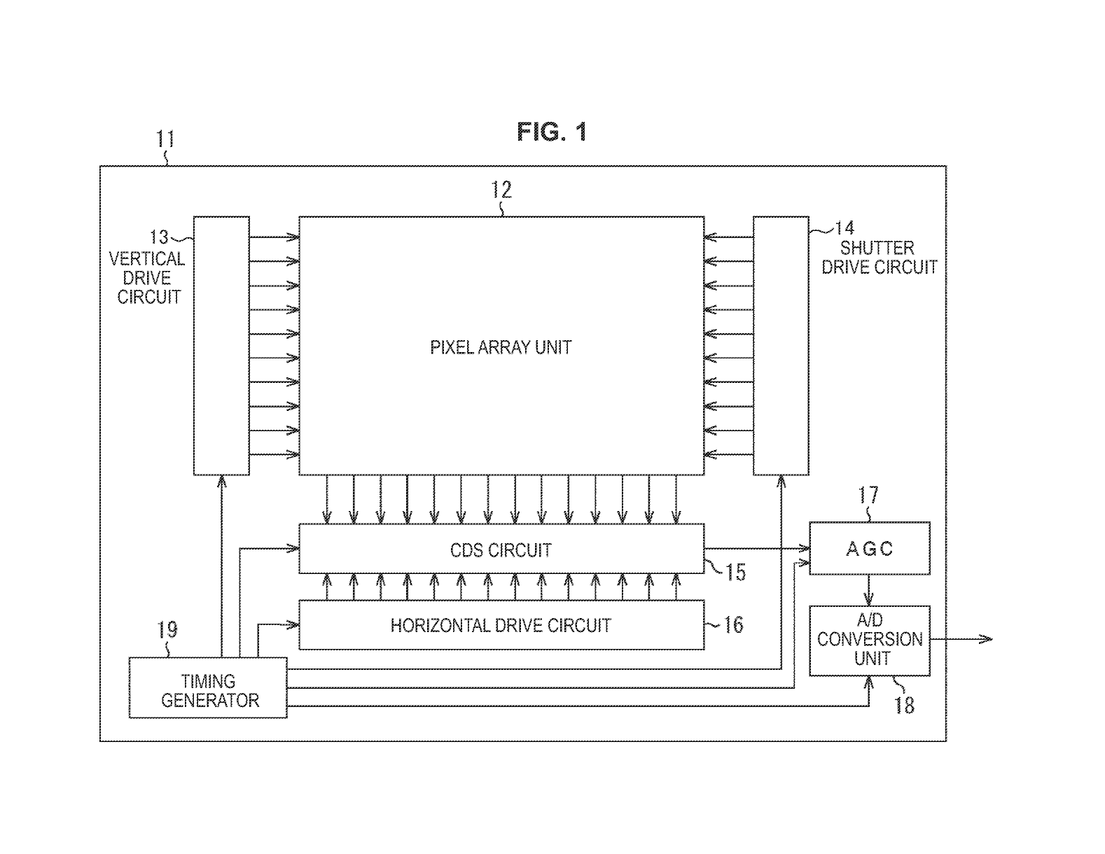

FIG. 1 is a block diagram showing an exemplary configuration of an embodiment of a solid-state imaging device to which the present technology is applied.

A solid-state imaging device 11 shown in FIG. 1 is configured as a CMOS (Complementary Metal Oxide Semiconductor) solid-state imaging device. The solid-state imaging device 11 includes a pixel array unit 12, a vertical drive circuit 13, a shutter drive circuit 14, a CDS (Correlated Doubled Sampling) circuit 15, a horizontal drive circuit 16, an AGC (Automatic Gain Controller) 17, an A/D (Analog/Digital) conversion unit 18, and a timing generator 19.

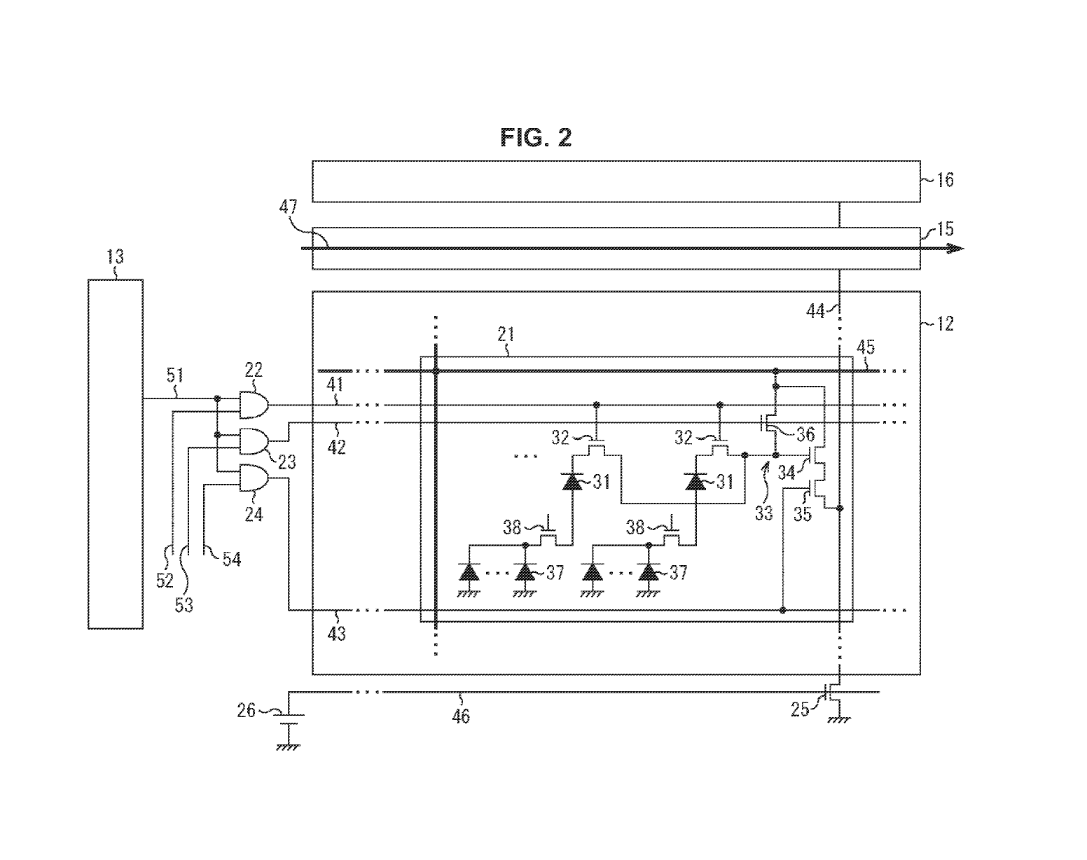

The pixel array unit 12 includes a plurality of pixels (for example, a pixel 21 in FIG. 2) that are arrayed in a two-dimensional manner, and each pixel includes one or a plurality of photoelectric conversion elements. To the pixel array unit 12, a plurality of signal wires for supplying signals from the vertical drive circuit 13 to the pixels are connected on a row basis, and a plurality of signal wires for outputting image signals from the pixels to the CDS circuit 15 are connected on a column basis.

The vertical drive circuit 13 sequentially supplies signals by which the plurality of pixels included in the pixel array unit 12 are selected on a row basis, through the signal wires.

The shutter drive circuit 14 sequentially supplies drive signals for performing a shutter drive, to the plurality of pixels included in the pixel array unit 12, on a row basis. For example, by regulating the interval between the drive signals to be output from the shutter drive circuit 14 and the signals to be output from the vertical drive circuit 13, it is possible to regulate the exposure time (electric charge accumulation time) of the pixels.

The CDS circuit 15 reads image signals from pixels on a row that is selected by the signal from the vertical drive circuit 13, and then performs a CDS process. That is, the CDS circuit 15 performs a process of taking the difference between pixel signals at levels depending on the electric charges accumulated in the pixels and pixel signals at reset levels of the pixels, and thereby, acquires signals indicating pixel values in which the fixed pattern noise for each pixel has been removed. Then, in accordance with the drive signals from the horizontal drive circuit 16, the CDS circuit 15 sequentially outputs the acquired signals, which indicate the pixel values, to the AGC 17.

The horizontal drive circuit 16 selects the pixels included in the pixel array unit 12, in an order in the column direction, and then outputs drive signals by which the signals indicating the pixel values are output, to the CDS circuit 15.

The AGC 17 amplifies the signals indicating the pixel values, which are supplied from the CDS circuit 15, by an appropriate gain, and then outputs them to the A/D conversion unit 18.

The A/D conversion unit 18 converts the analog signals supplied from the AGC 17, into digital numeral values, and then outputs the obtained pixel data to the exterior of the solid-state imaging device 11.

The timing generator 19 generates signals indicating the timings necessary for the drive of the blocks of the solid-state imaging device 11, based on a clock signal with a predetermined frequency, and then supplies them to the respective blocks.

Here, FIG. 1 shows an example of a configuration of the solid-state imaging device 11, and it is possible to adopt, for example, a configuration in which the A/D conversion unit 18 is not included in the interior of the solid-state imaging device 11, or a configuration in which the A/D conversion unit is included for each column of the pixels. The solid-state imaging device 11 is configured to have a plurality of output systems, by including one or more CDS circuits 15, or by providing a plurality of the AGCs 17 and the A/D conversion units 18.

### [The Pixels of the Pixel Array Unit and Its Peripheral Circuits]

Next, the pixels of the pixel array unit 12 and its peripheral circuits will be described with reference to FIG. 2.

As described above, in the pixel array unit 12, the plurality of pixels are arrayed in a two-dimensional manner, but FIG. 2 illustrates one pixel 21 of them and the illustration of the other pixels is omitted for simplification. As shown in FIG. 2, the peripheral circuits of the pixel array unit 12 are configured to include AND elements 22 to 24 disposed for each row of the pixels 21, a transistor 25 disposed for each column of the pixels 21, and a constant potential source 26.

The pixel 21 includes photodiodes (PDs) 31, transfer gates 32, a floating diffusion (FD) 33, an amplification transistor 34, a selection transistor 35, a reset transistor 36, PDs 37 and transfer gates 38. The pixel 21 is configured as a divided pixel that includes a plurality of PDs 31 and PDs 37 as plurally-divided photoelectric conversion elements.

The pixel 21 is connected with a transfer signal wire 41, reset signal wire 42 and selection signal wire 43 through which common signals are supplied to the pixels arrayed in the row direction, and the CDS circuit 15 is connected with a pixel output wire 44 through which a pixel signal is output. A predetermined power potential is supplied to the pixel 21 through a power potential supply wire 45.

The PDs 31 are photoelectric conversion elements that perform the photoelectric conversion of the light radiated to the pixel 21, generate electric charges and accumulate the electric charges, and are plurally provided for one pixel 21.

The transfer gates 32 transfer the electric charges accumulated in the PDs 31 to the FD 33, in accordance with transfer signals supplied through the transfer signal wire 41. The transfer gates 32 are plurally provided depending on the number of the PDs 31.

The FD 33 is a floating diffusion region formed at the connection point between the plurality of transfer gates 32 and the gate electrode of the amplification transistor 34, and temporarily accumulates the electric charges transferred from the PDs 31 through the transfer gates 32. That is, the electric potential of the gate electrode of the amplification transistor 34 increases depending on the electric charges accumulated in the FD 33.

The amplification transistor 34, whose drain is connected with the power potential supply wire 45, converts the electric charges accumulated in the FD 33 into a pixel signal having a level depending on the electric potential, and then outputs it.

To the selection transistor 35, a selection signal for selecting the pixel 21 to output the pixel signal is supplied through the selection signal wire 43, and the selection transistor 35 connects the amplification transistor 34 to the pixel output wire 44, in accordance with the selection signal.

The reset transistor 36, whose drain is connected with the power potential supply wire 45, resets the electric charges accumulated in the FD 33, in accordance with a reset signal supplied through the reset signal wire 42.

Similarly to the PDs 31, the PDs 37 are photoelectric conversion elements that perform the photoelectric conversion of the light radiated to the pixel 21, generate electric charges and accumulate the electric charges, and are plurally provided for one pixel 21.

Similarly to the transfer gates 32, the transfer gates 38 transfer the electric charges accumulated in the plurality of PDs 37 to the PDs 31, in accordance with transfer signals supplied through the transfer signal wire 41. The transfer gates 38 are also plurally provided depending on the number of the PDs 31.

Thus, the pixel 21 has a configuration in which the plurality of PDs are included as the divided pixel, and in which the PDs 31 of them share the FD 33 through the transfer gates 32 and the PDs 37 transfer the electric charges to the PDs 31 through the transfer gates 38. Also, although not shown in the figure, the pixel 21 can have a configuration in which some of the plurality of PDs 37 transfer the electric charges to the adjacent PDs 37 through the transfer gates 38.

The transistor 25 supplies a constant current to the pixel output wire 44. That is, the constant current is supplied from the transistor 25 to the amplification transistor 34 of the pixel 21 that is selected for the output of the pixel signal, and thereby, the amplification transistor 34 operates as a source follower. Thereby, an electric potential having a predetermined constant voltage difference from the gate potential of the amplification transistor 34 is applied to the pixel output wire 44.

The constant potential source 26 supplies a constant potential to the gate electrode of the transistor 25 through a constant potential supply wire 46 such that the transistor 25 performs the saturation region operation to supply the constant current.

In the AND element 22, the output terminal is connected with the gate electrodes of the transfer gates 32 and transfer gates 38 through the transfer signal wire 41. Furthermore, in the AND element 22, one input terminal is connected with an output terminal of the vertical drive circuit 13 through a signal wire 51, and the other input terminal is connected with a terminal from which a pulsed transfer signal is output in accordance with the drive timing, through a signal wire 52.

In the AND element 23, the output terminal is connected with the gate electrode of the reset transistor 36 through the reset signal wire 42. Furthermore, in the AND element 23, one input terminal is connected with the output terminal of the vertical drive circuit 13 through the signal wire 51, and the other input terminal is connected with a terminal from which a pulsed reset signal is output in accordance with the drive timing, through a signal wire 53.

In the AND element 24, the output terminal is connected with the gate electrode of the selection transistor 35 through the selection signal wire 43. Furthermore, in the AND element 24, one input terminal is connected with the output terminal of the vertical drive circuit 13 through the signal wire 51, and the other input terminal is connected with a terminal from which a pulsed selection signal is output in accordance with the drive timing, through a signal wire 54.

By such a configuration, the solid-state imaging device 11 supplies the transfer signal, the reset signal and the selection signal to the pixels 21 that are disposed on a row selected by the vertical drive circuit 13, through the transfer signal wire 41, the reset signal wire 42 and the selection signal wire 43, respectively.

### [The Drive Timing of the Pixel]

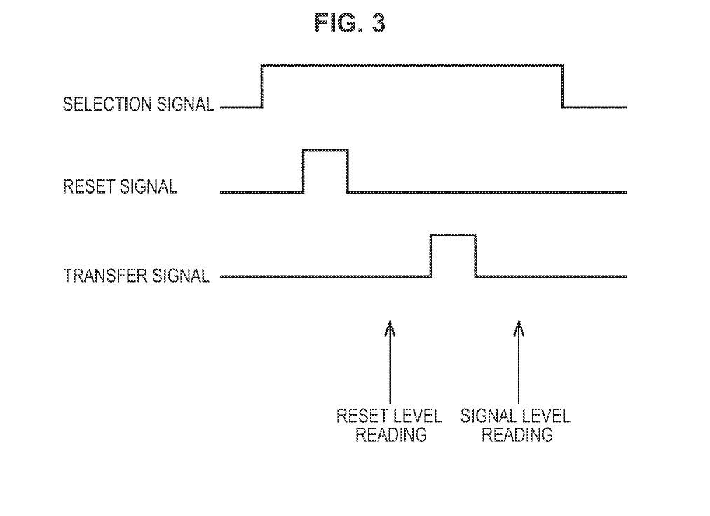

Next, the drive signal to be supplied to the pixel 21 will be described with reference to FIG. 3.

The selection signal shown in FIG. 3 is supplied to the selection transistor 35 through the selection signal wire 43, the reset signal is supplied to the reset transistor 36 through the reset signal wire 42, and the transfer signal is supplied to the transfer gates 32 and the transfer gates 38 through the transfer signal wire 41.

At the timing of the start of a reading period when the pixel signal is read from the pixel 21, the selection signal becomes the H (High) level and the selection transistor 35 becomes in a conduction state, resulting in a state in which the signal of the pixel 21 can be output to the CDS circuit 15 through the pixel output wire 44.

Thereafter, the reset signal becomes the H level and the reset transistor 36 becomes in a conduction state, and thereby the electric charges accumulated in the FD 33 are reset. Then, the reset signal becomes the L (Low) level and thereby the reset transistor 36 becomes in a non-conduction state, and, after the reset is completed, the pixel signal at the reset level is read to the CDS circuit 15.

Subsequently, the transfer signal becomes the H level, and thereby the transfer gates 32 and the transfer gates 38 become in a conduction state so that the electric charges accumulated in the PDs 37 are transferred to the PDs 31 while the electric charges accumulated in the PDs 31 are transferred to the FD 33. Then, the transfer signal becomes the L level and thereby the transfer gates 32 and the transfer gates 38 become in a non-conduction state, and, after the transfer of the electric charges is completed, the pixel signal at a level depending on the electric charges accumulated in the FD 33 is read to the CDS circuit 15.

Thus, in the solid-state imaging device 11, the pixel signal at the reset level and the pixel signal at a level depending on the electric charges accumulated in the FD 33 are read to the CDS circuit 15. Then, the CDS circuit 15 performs a CDS process, resulting in a cancellation of the fixed pattern noise that is generated by the variation in the threshold voltage of the amplification transistor 34 for each pixel 21 and the like.

The CDS circuit 15 outputs a signal that indicates the pixel value of the pixel 21 on a column selected by the horizontal drive circuit 16, to the AGC 17 in FIG. 1 through a horizontal signal wire 47.

### [The Structure of the Pixel]

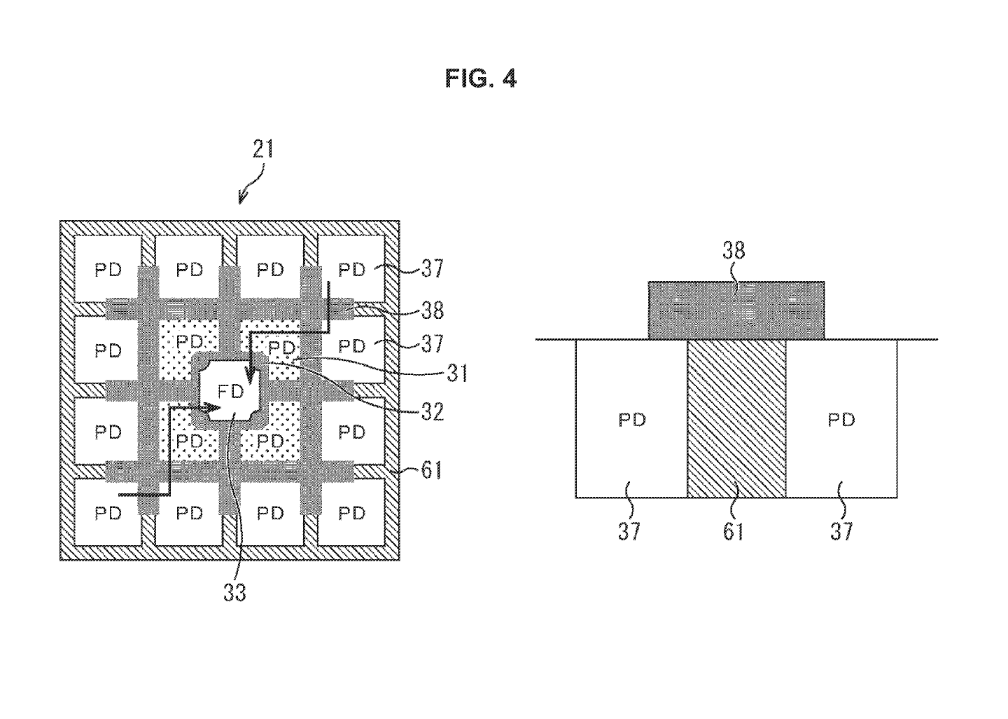

Here, the structure of the pixel 21 will be described with reference to FIG. 4. The left side of FIG. 4 shows an example of the planar structure of the pixel 21, and the right side of FIG. 4 shows an example of the cross-sectional structure of the pixel 21.

As shown in the left side of FIG. 4, the pixel 21 includes 16-division PDs (16 PDs) in a 4×4 manner, and the FD 33 is disposed at the center. In the pixel 21 shown in FIG. 4, the 4 PDs 31 on the inner side of the 16 PDs transfer the electric charges to the FD 33 through the transfer gates 32.

Furthermore, in the pixel 21, the transfer gates 38, by which the 12 PDs 37 on the outer side of the 16 PDs transfer the electric charges to the adjacent PDs 37 or PDs 31, are disposed in a grid-like manner. As shown in the right side of FIG. 4, the transfer gates 38 are formed on an element separation region 61 that is formed at the intervals with the adjacent PDs 37 or PDs 31. The element separation region 61 is formed by ion implantation.

In the pixel 21, the impurity concentration (phosphorus, arsenic, boron and the like) of the PD increases as the distance between the PD and the FD 33 shortens. Concretely, in the pixel 21, the 4 PDs 31 on the inner side, which are closer to the FD 33 compared to the 12 PDs 37 on the outer side, have a higher impurity concentration than the 12 PDs 37 on the outer side.

According to the above structure, in the pixel 21, the electric charges from the PDs 37 are transferred to the PDs 31 through the transfer gates 38, and the electric charges from the PDs 31 are transferred to the FD 33 through the transfer gates 32. That is, even when the photoelectric conversion element is more divided than the 4-division in a 2×2 manner, it is possible to equalize the positional relation to the electric charge transfer target for each photoelectric conversion element and suppress the variation in electric charge transfer characteristic. Furthermore, in the configuration of the divided pixel, it is possible to increase the PN junction area in the lateral cross-section direction, and therefore, it is possible to obtain more saturation signal amount. Thus, the divided pixel makes it possible to unlimitedly increase the division number of the photoelectric conversion element and to easily design and form a divided pixel with a higher flexibility, and therefore can exhibit the above described effect.

Furthermore, in the pixel 21, since the impurity concentration of the PD increases as the distance between the PD and the FD 33 shortens, it is possible to regulate the electric charge transfer from the PDs 37 to the PDs 31 and the electric charge transfer from the PDs 31 to the FD 33. Here, depending on the cell size or the layout of the transfer gates, such a concentration gradient does not have to be provided.

### [The Impurity Concentration of the Element Separation Region]

In the structure described with reference to FIG. 4, the element separation region 61 is modulated by the transfer gate 38, and the electric charge is transferred between the PDs. However, in the case of forming the element separation region 61 on an element separation condition of an equivalent concentration to an ordinary MOS process, there is a possibility that the reversal characteristic is not sufficiently provided when the transfer gate 38 is ON (when the transfer signal is at the H level).

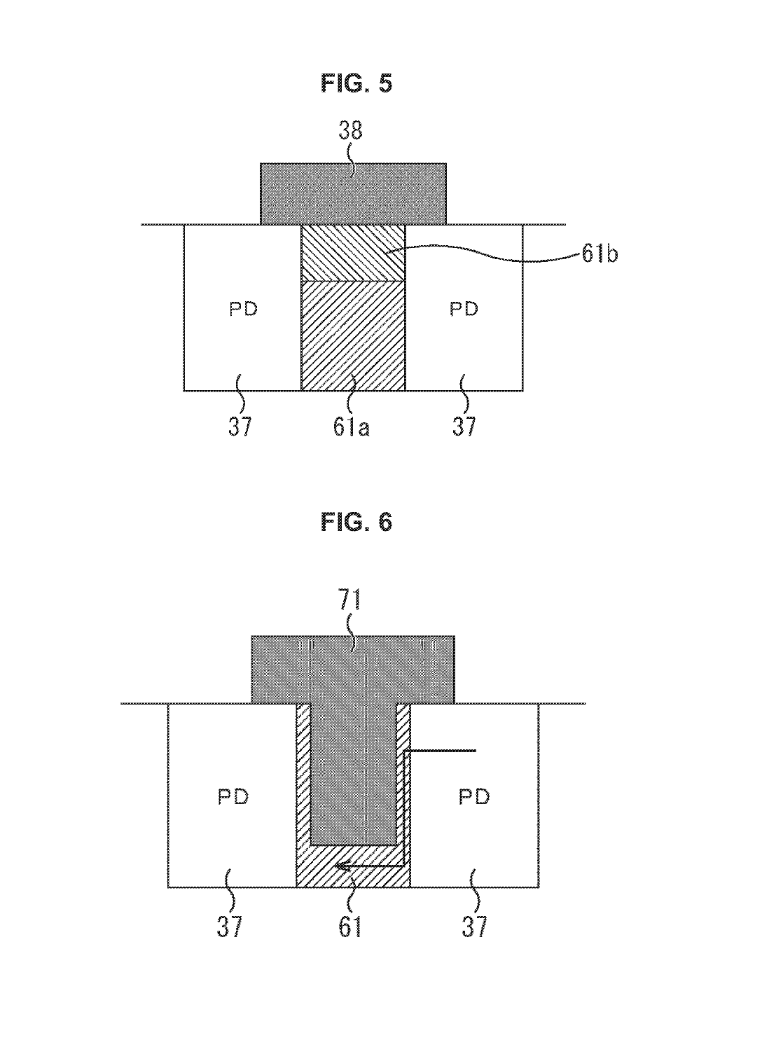

Hence, when forming the element separation region 61 by ion implantation, the impurity concentration of the element separation region 61 is decreased as the cross-section height increases. Concretely, as shown in FIG. 5, in the element separation region, the impurity concentration of a region 61b where the cross-section height is low is decreased than the impurity concentration of a region 61a where the cross-section height is high. Thereby, it is possible to improve the reversal characteristic of a part in the element separation region 61 that is an electric charge transfer path when the transfer gate 38 is ON.

### [Implanted Transfer Gate]

The transfer gate 38 may be formed so as to be implanted in a trench formed on the element separation region 61.

Concretely, as shown in FIG. 6, it is allowable to provide a transfer gate 71 that is formed so as to be implanted in a trench formed on the element separation region 61, instead of the transfer gate 38. In the element separation region 61, the trench in which the transfer gate 71 is implanted is formed on the whole grid-like region in FIG. 4 where the transfer gate 38 is disposed. That is, the transfer gate 71 has a part (implanted part) that is implanted in the trench, over the whole of the grid-like formation. In this structure, the electric charge transfer path in the element separation region 61 is the underside of the implanted part of the transfer gate 71, as shown by the arrow in FIG. 6.

Such a structure increases part in which the element separation region 61 is modulated. Therefore, it is possible to enhance the change rate (modulation degree) of the channel potential of the element separation region 61 with respect to the voltage applied to the transfer gate 71, and to securely perform the switching between the element separation state when the transfer gate 71 is OFF and the electric charge transfer state when the transfer gate 71 is ON.

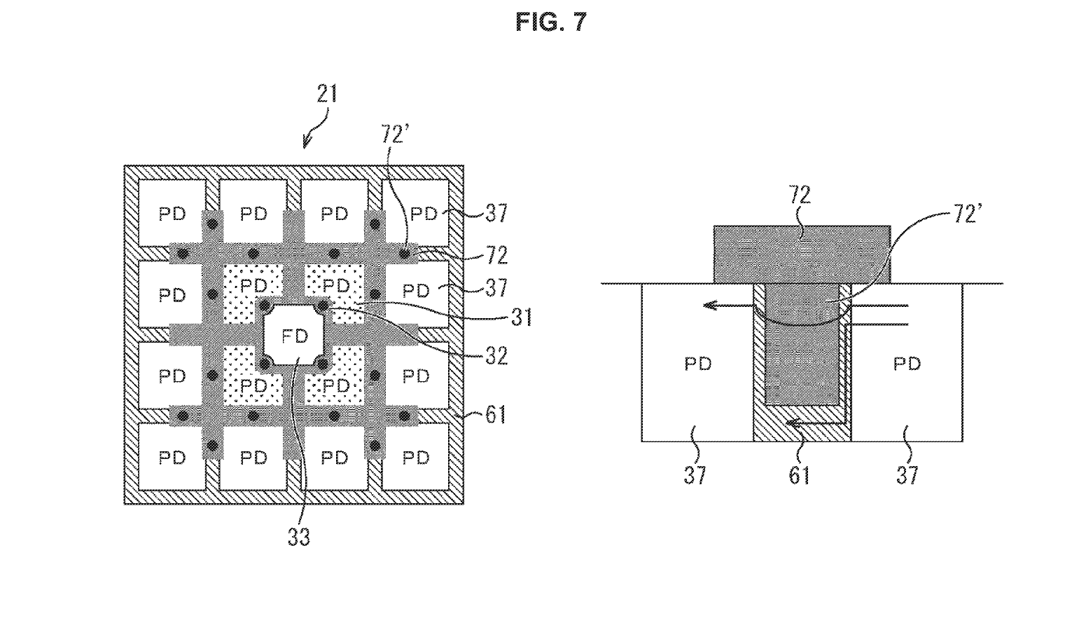

Here, in the example of FIG. 6, the transfer gate has the implanted part over the whole of the grid-like formation, but may have the implanted part only at a part of the grid-like formation. Concretely, as shown in the left side of FIG. 7, the implanted parts 72′ shown by the black circles in the figure may be provided at parts of the transfer gate 72 that is formed in a grid-like shape.

In such a structure, the electric charge transfer path in the element separation region 61 is the underside and lateral side of the implanted part of the transfer gate 72, as shown by the arrows in the right side of FIG. 7, and it is possible to improve the electric charge transfer characteristic compared to the structure in FIG. 6.

### [An Example of the Transfer Gate for Each PD Group]

In the above, the transfer gate is formed so as to transfer the electric charges of all the PDs of the pixel 21 at the same timing, but it may be formed so as to transfer the electric charges for each PD group, which is an aggregate of the PDs.

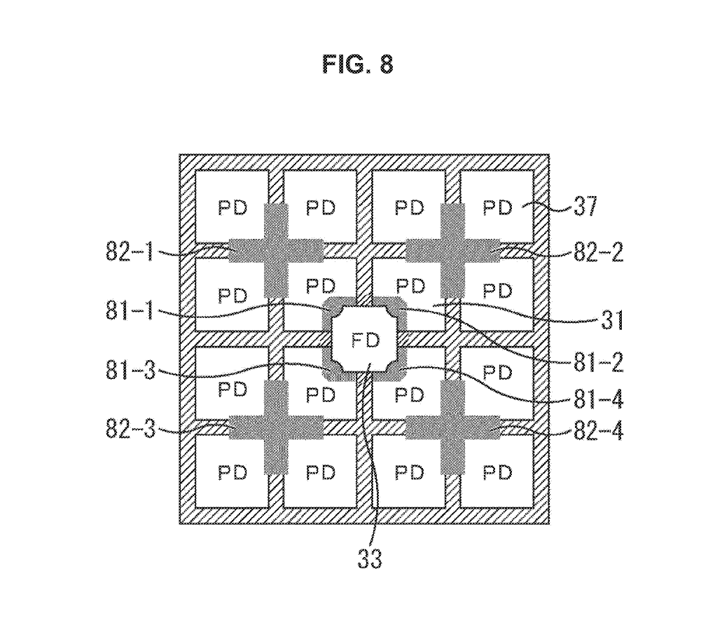

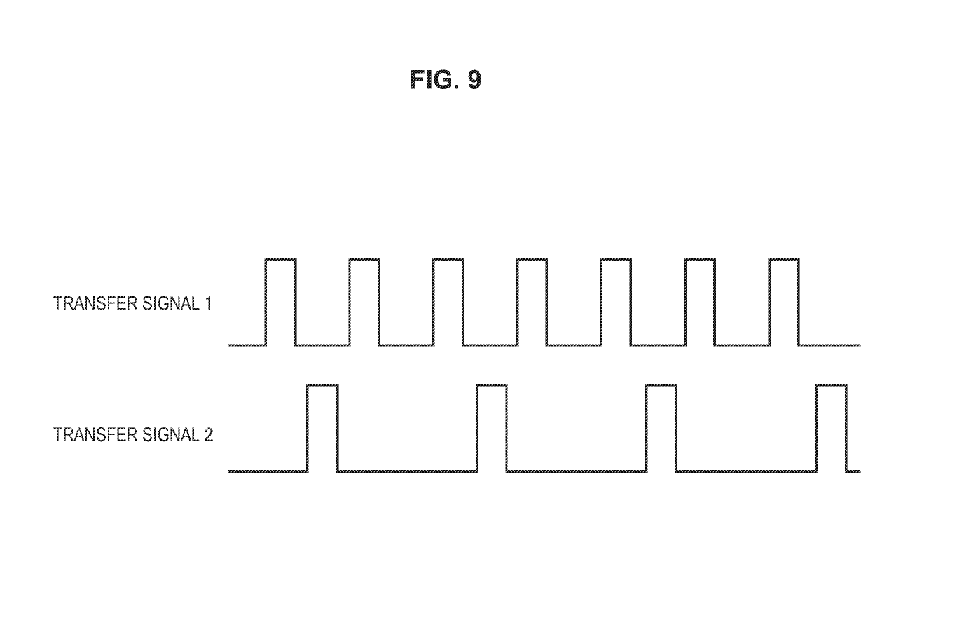

For example, as shown in FIG. 8, the 16 (=4×4) PDs (PDs 31, 37) may be separated into PD groups that include the 4 PDs in the upper left, the 4 PDs in the upper right, the 4 PDs in the lower left and the 4 PDs in the lower right, respectively, and transfer gates 81-1 to 81-4, 82-1 to 82-4 may be formed for the respective PD groups. In this case, for example, the electric charges from the PD group of the 4 PDs in the upper left are transferred from the PDs 37 through the transfer gate 82-1 to the PD 31, and further are transferred from the PD 31 through the transfer gate 81-1 to the FD 33. As for the other PD groups, the electric charges are transferred similarly.

In such a configuration, it is possible to control the timing of the electric charge transfer for each PD group, depending on the imaging mode or the imaging environment.

For example, a transfer signal 1 shown in FIG. 9 is supplied to the transfer gates 81-1, 81-2, 82-1, 82-2 of the PD groups in the upper left and upper right, and a transfer signal 2 is supplied to the transfer gates 81-3, 81-4, 82-3, 82-4 of the PD groups in the lower left and lower right. By such an electric charge transfer timing, it is possible to obtain a short accumulation-time signal and a long accumulation-time signal, and by synthesizing these at the subsequent stage, it is possible to obtain an image with a broad dynamic range.

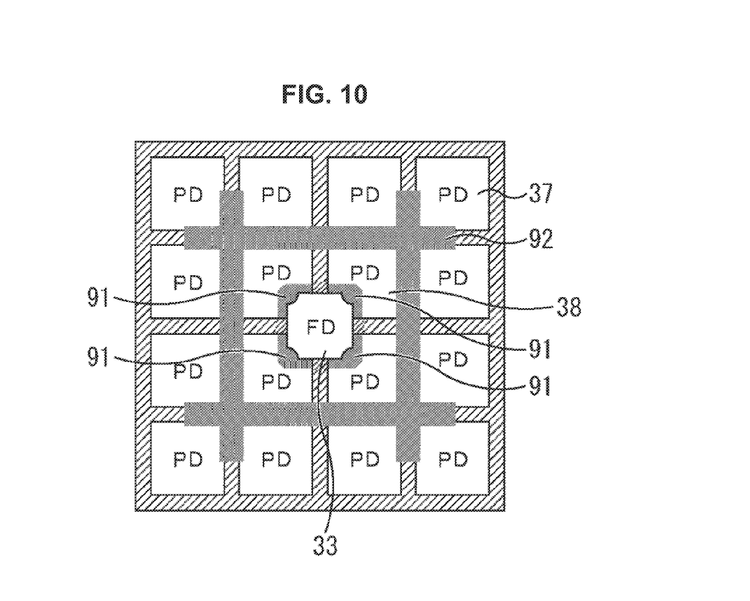

Also, as shown in FIG. 10, the 16 (=4×4) PDs (PDs 31, 37) may be separated into a PD group including the 4 PDs on the inner side and a PD group including all the 16 PDs, and transfer gates 91, 92 may be formed for the respective PD groups.

In such a configuration, also, it is possible to control the timing of the electric charge transfer for each PD group, depending on the imaging mode or the imaging environment.

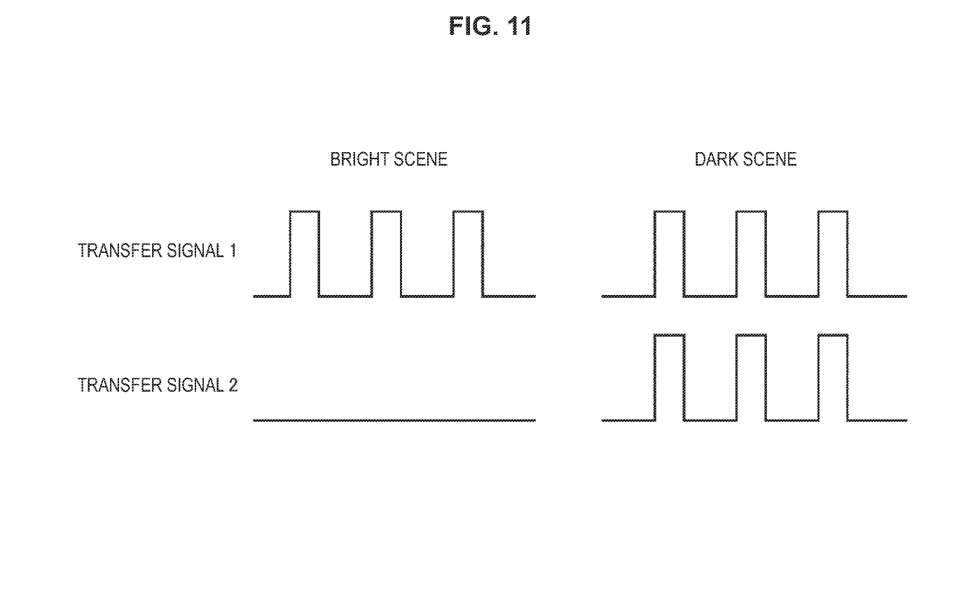

For example, a transfer signal 1 shown in FIG. 11 is supplied to the transfer gates 91, and a transfer signal 2 is supplied to the transfer gate 92. Thereby, in a bright scene, only the transfer gates 91 are driven so that only the electric charges from the 4 PDs (PDs 31) on the inner side are transferred to the FD 33, and therefore the signal can be read at a low sensitivity. In a dark scene, the transfer gates 91 and the transfer gate 92 are driven so that the electric charges from all the 16 PDs are transferred to the FD 33, and therefore the signal can be read at a high sensitivity. That is, it is possible to obtain an image depending on the scene.

From the above, by controlling the drive timing for each PD group depending on the imaging mode or the imaging environment, it is possible to control the accumulation time and the signal amount, and to obtain an image corresponding to the imaging mode or the imaging environment. Here, the combination way of the PDs for configuring the PD groups is not limited to the above, and another combination way can be applied.

### [A Production Process of the Solid-State Imaging Device]

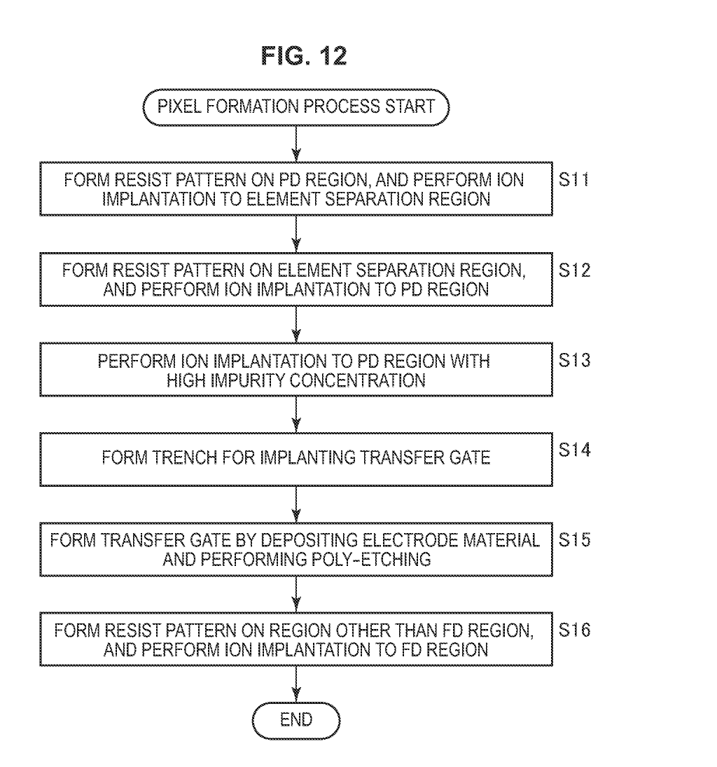

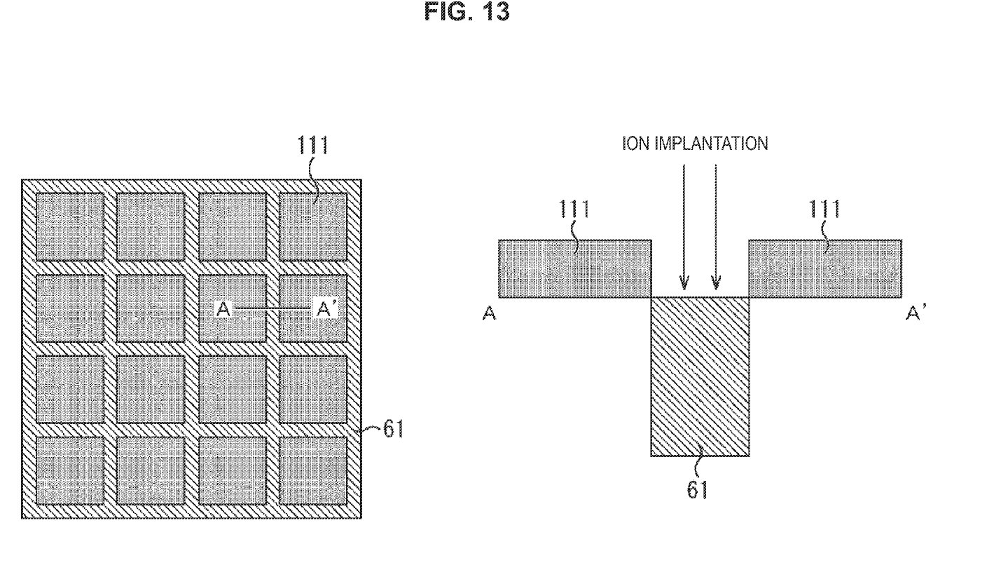

Next, a formation process of the pixel 21 will be described with reference to FIG. 12 to FIG. 19. FIG. 12 is a flowchart for explaining a formation process of the pixel 21, and FIG. 13 to FIG. 19 show plan diagrams and cross-section diagrams of the pixel 21 in stages of the formation. In FIG. 13 to FIG. 19, the cross-section diagrams shown on the right sides illustrate the cross-sections of the pixel 21 taken along line A-A′ in the plan diagrams shown on the left sides. Hereinafter, a formation process of the pixel 21 described with reference to FIG. 7 will be described.

First, in step S11, as shown in FIG. 13, a resist pattern 111 is formed on a PD region in a semiconductor substrate, which is a region for forming the PD and is in a region on which a pixel region is to be formed, and then, the ion implantation is performed to the element separation region 61.

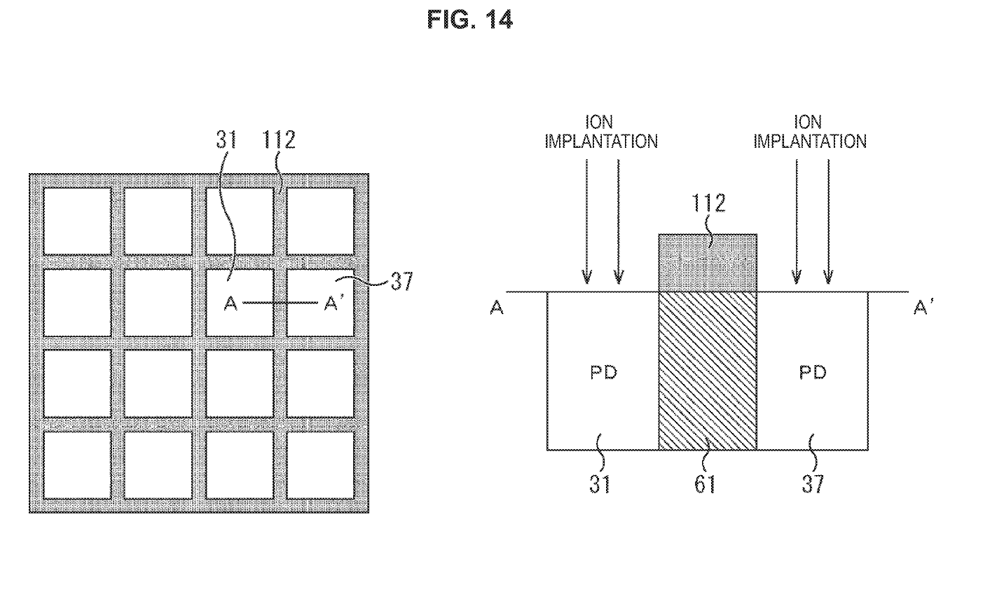

In step S12, as shown in FIG. 14, a resist pattern 112 is formed on the element separation region 61, and then, the ion implantation is performed to the PD region.

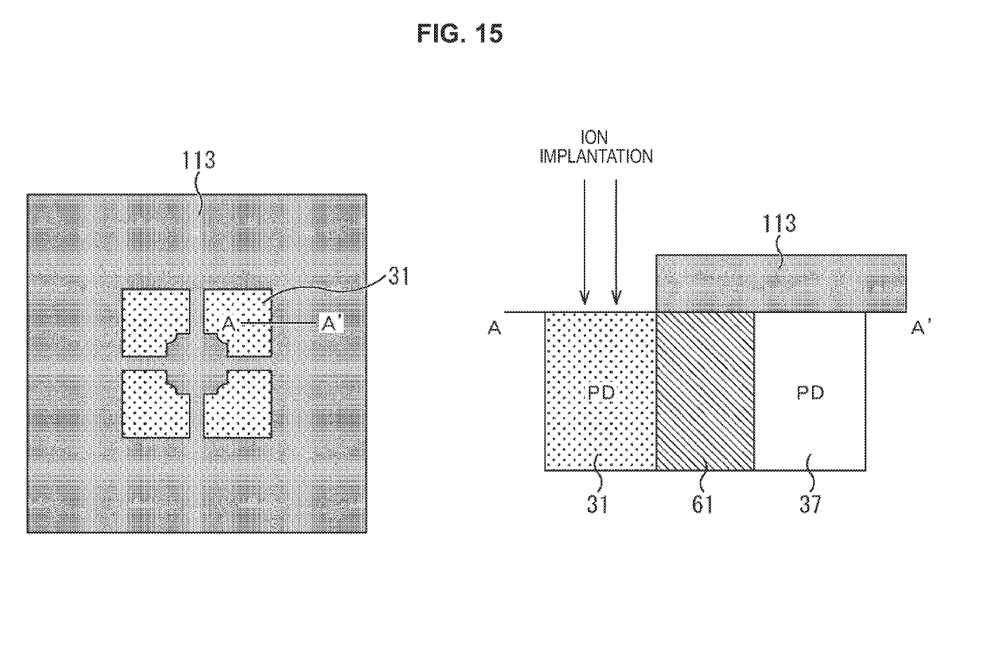

In step S13, as shown in FIG. 15, a resist pattern 113 is formed on a region other than the PD region for the PD 31 with a high impurity concentration, and then, the ion implantation is performed to the PD region for the PD 31.

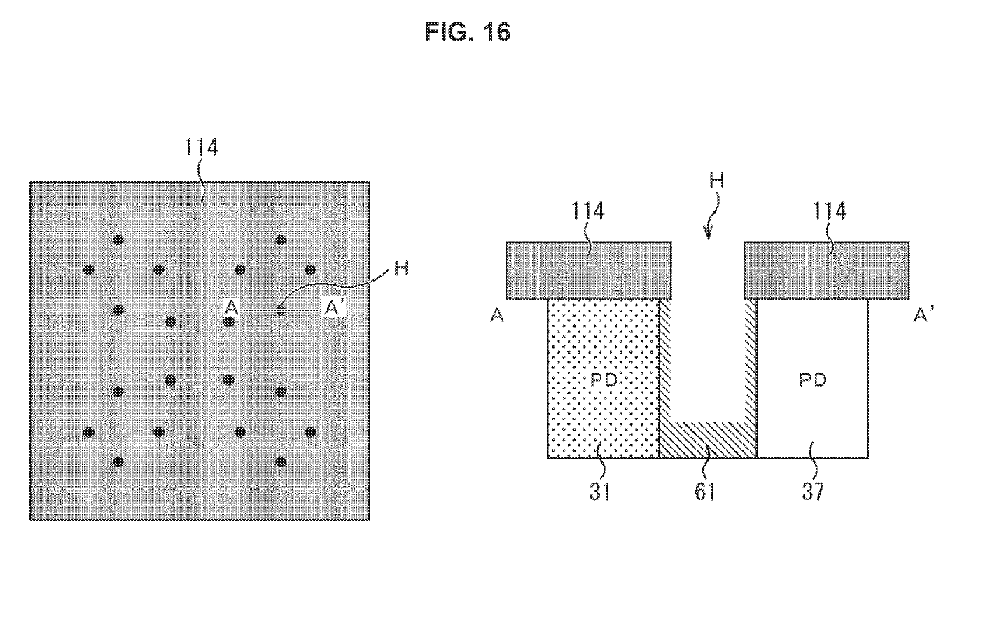

In step S14, as shown in FIG. 16, a resist pattern 114 is formed, and then, a trench H for implanting the implanted part 72′ of the transfer gate 72 is formed. The shape of the trench H, viewed from the upper surface, may be a circular shape, or may be a rectangular shape.

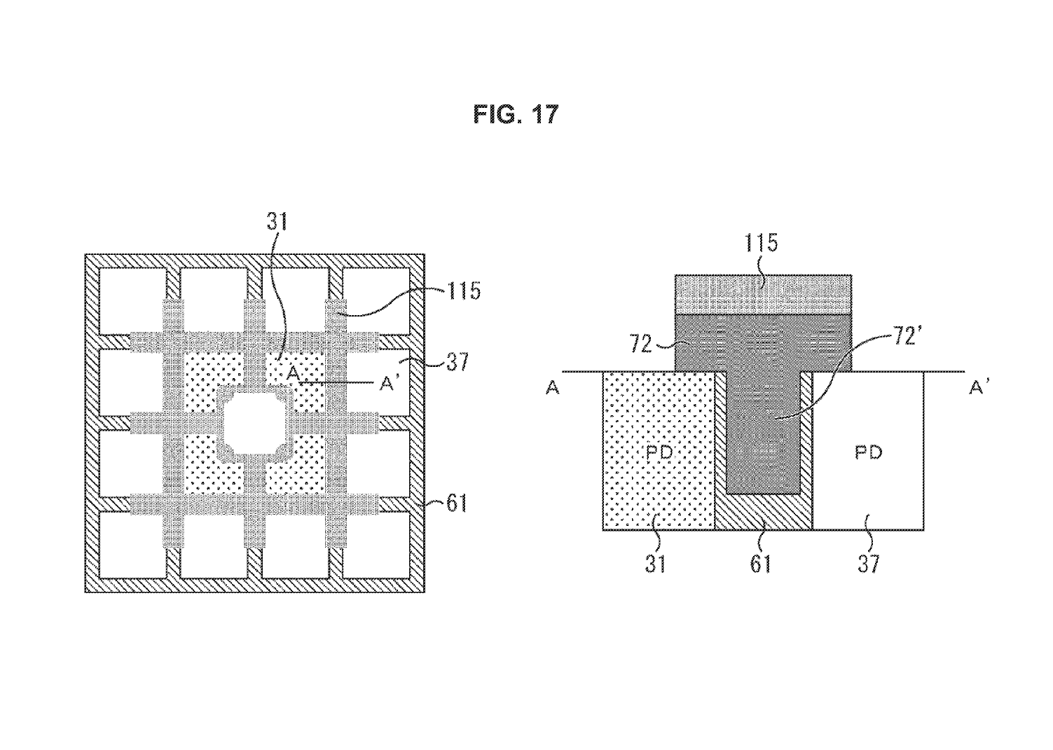

In step S15, the electrode material of the transfer gate 72 is deposited on the whole surface of the pixel region. Then, as shown in FIG. 17, a resist pattern 115 is formed on a region for forming the transfer gate 72 and the poly-etching is performed, and thereby, the transfer gate 72 is formed.

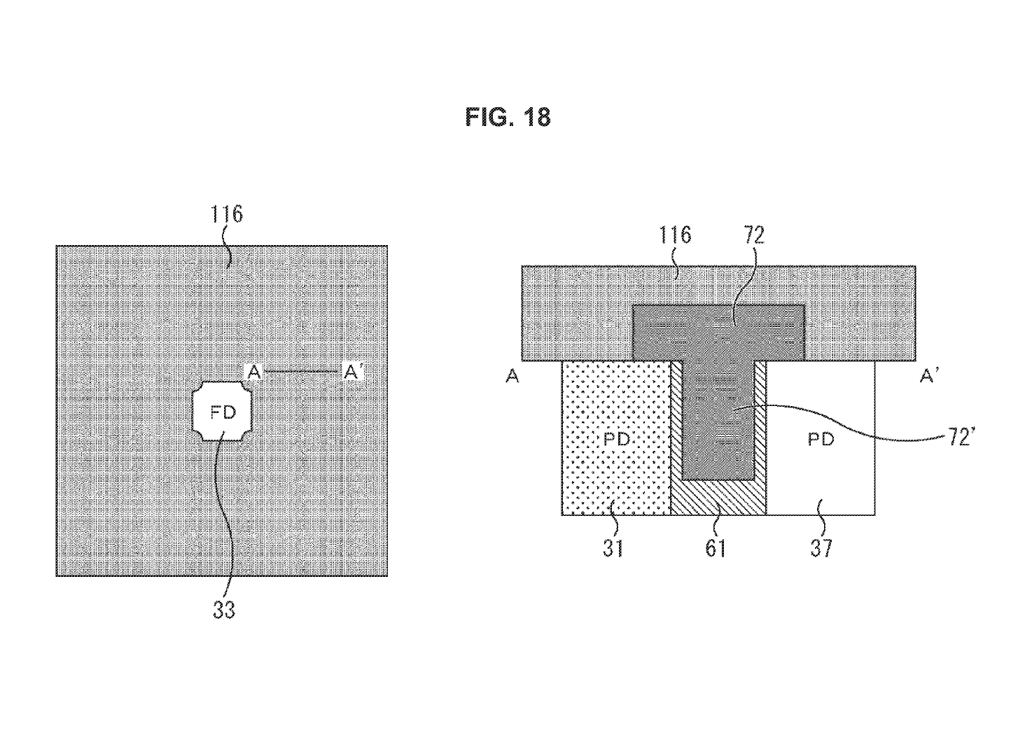

In step S16, as shown in FIG. 18, a resist pattern 116 is formed on a region other than an FD region for forming the FD 33, and then, the ion implantation is performed to the FD region. Thus, the pixel 21 shown in FIG. 7 is formed.

According to the above process, it is possible to unlimitedly increase the division number of the photoelectric conversion element in the divided pixel, and to easily design and form a divided pixel with a higher flexibility.

Here, in the formation process of the pixel 21, the processes such as the ion implantation to the element separation region 61 and the ion implantation to the PD region do not have to be performed in the above procedure, and may be performed in another procedure.

### [Alternative Examples of the Planar Structure of the Pixel]

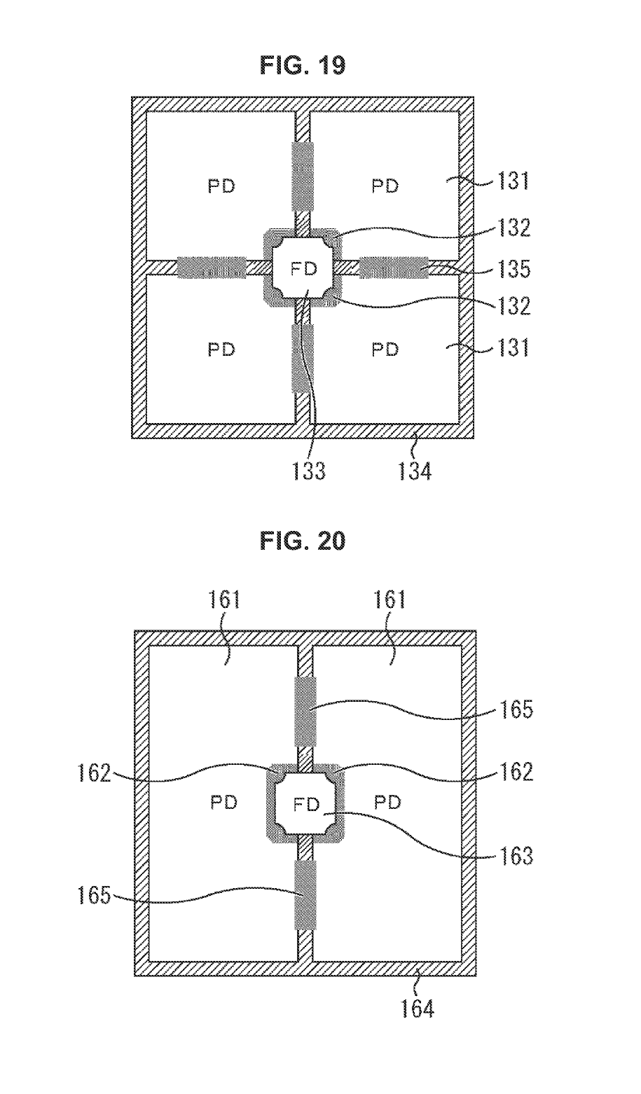

In the above, the pixel that includes the 16-division PDs in a 4×4 manner has been described. Naturally, the present technology can be applied to a pixel shown in FIG. 19 that includes 4-division PDs in a 2×2 manner, and a pixel shown in FIG. 20 that includes 2-division PDs in a 1×2 manner.

The pixel shown in FIG. 19 includes 4-division PDs (4 PDs) 131 in a 2×2 manner, and an FD 133 is disposed at the center. In the pixel shown in FIG. 19, the 4 PDs 131 transfer the electric charges to the FD 133 through transfer gates 132. Furthermore, in the pixel shown in FIG. 19, transfer gates 135, by which the electric charges are transferred to the adjacent PDs 131, are formed on an element separation region 134 that is formed at the intervals with the adjacent PDs 131.

The pixel shown in FIG. 20 includes 2-division PDs (2 PDs) 161 in a 1×2 manner, and an FD 163 is disposed at the center. In the pixel shown in FIG. 20, the 2 PDs 161 transfer the electric charges to the FD 163 through transfer gates 162. Furthermore, in the pixel shown in FIG. 20, transfer gates 165, by which the electric charges are transferred to the adjacent PD 161, are formed on an element separation region 164 that is formed at the interval with the adjacent PD 161.

Naturally, the present technology can be applied to a pixel that includes 25-division PDs in a 5×5 manner or PDs divided into a more number, and a pixel that includes PDs divided in an arrangement other than a matrix manner.

### [An Exemplary Configuration of an Electronic Apparatus]

The solid-state imaging device 11 according to an embodiment of the present technology can be incorporated not only in imaging apparatuses such as a digital still camera and a digital video camera but also in various electronic apparatuses such as a mobile phone and a personal computer.

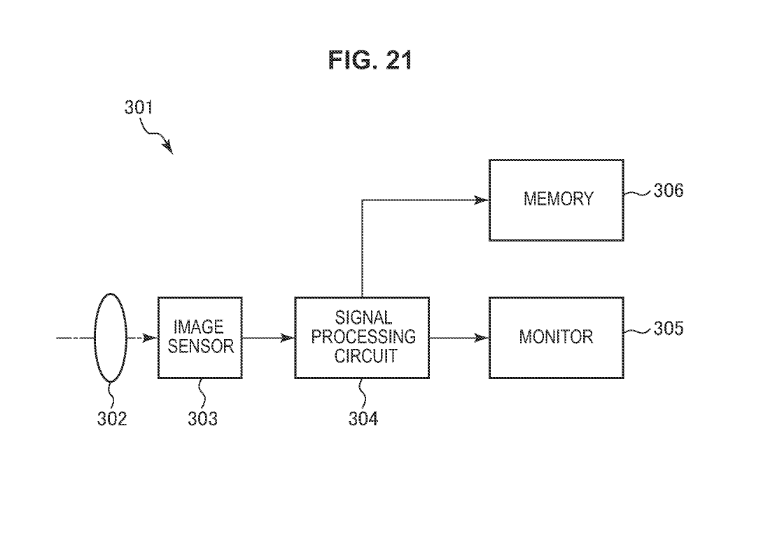

FIG. 21 is a block diagram showing an exemplary configuration of an electronic apparatus.

As shown in FIG. 21, an electronic apparatus 301 includes an optical system 302, an image sensor 303, a signal processing circuit 304, a monitor 305 and a memory 306, and has a function to take a still image and a moving image.

The optical system 302, which is configured to include a single or a plurality of lenses, guides the picture light (incident light) from an object, to the image sensor 303, and forms a picture on the light receiving surface of the image sensor 303.

As the image sensor 303, the solid-state imaging device 11 that includes the pixels 21 with the above described configuration is applied. An electric charge is accumulated in the image sensor 303 for a certain period, depending on the picture formed on the light receiving surface through the optical system 302. Then, a signal depending on the electric charge accumulated in the image sensor 303 is supplied to the signal processing circuit 304.

The signal processing circuit 304 performs various signal processes to the signal electric charge output from the image sensor 303. An image (image data) obtained by the signal processes of the signal processing circuit 304 is supplied to the monitor 305 to be displayed, and is supplied to the memory 306 to be stored (recorded).

In the electronic apparatus 301 with such a configuration, the solid-state imaging device 11 that includes the pixels 21 with the above described configuration is applied as the image sensor 303, and thereby, it is possible to suppress the variation in electric charge transfer characteristic and improve the image quality.

The solid-state imaging device 11 according to an embodiment of the present technology can be adopted not only to a backside-illumination-type or frontside-illumination-type CMOS solid-state imaging device, but also to a CCD solid-state imaging device and the like.

Embodiments of the present technology are not limited to the above described embodiment, and various alternations are possible in the range without departing from the spirit of the present technology.

Additionally, the present technology may also be configured as below.
(1) A solid-state imaging device including:
   a pixel array unit in which pixels are arrayed in a two-dimensional manner, each of the pixels including a plurality of photoelectric conversion elements and a floating diffusion configured to accumulate an electric charge from the plurality of photoelectric conversion elements,
   wherein the floating diffusion is shared by at least two or more of the photoelectric conversion elements, and
   wherein one or more of the plurality of photoelectric conversion elements include a transfer gate configured to transfer an electric charge between the photoelectric conversion elements that are adjacent.
(2) The solid-state imaging device according to (1),
   wherein, of the plurality of photoelectric conversion elements, the photoelectric conversion elements except the photoelectric conversion elements sharing the floating diffusion include the transfer gate, and
   wherein the transfer gate is formed on a separation region that is formed between the photoelectric conversion elements that are adjacent.
(3) The solid-state imaging device according to (2),
   wherein an impurity concentration of the separation region decreases as a cross-section height thereof increases.
(4) The solid-state imaging device according to (2),
   wherein at least part of the transfer gate is implanted in a trench formed in the separation region.
(5) The solid-state imaging device according to any one of (2) to (4),
   wherein an impurity concentration of the photoelectric conversion element increases as a distance between the photoelectric conversion element and the floating diffusion shortens.
(6) The solid-state imaging device according to (2),
   wherein the transfer gate is formed for each photoelectric conversion element group, the photoelectric conversion element group being an aggregate of the photoelectric conversion elements.
(7) The solid-state imaging device according to (6),
   wherein a drive signal driving the transfer gate is supplied to the transfer gate for each photoelectric conversion element group depending on an imaging mode.
(8) The solid-state imaging device according to (6),
   wherein a drive signal driving the transfer gate is supplied to the transfer gate for each photoelectric conversion element group depending on an imaging environment.
(9) A production method of a solid-state imaging device including a pixel array unit in which pixels are arrayed in a two-dimensional manner, each of the pixels including a plurality of photoelectric conversion elements and a floating diffusion configured to accumulate an electric charge from the plurality of photoelectric conversion elements, the production method including:
   forming the floating diffusion shared by at least two or more of the photoelectric conversion elements; and
   forming a transfer gate configured to transfer an electric charge between the photoelectric conversion elements that are adjacent, for one or more of the plurality of photoelectric conversion elements.
(10) An electronic apparatus including:
   a solid-state imaging device including:
      a pixel array unit in which pixels are arrayed in a two-dimensional manner, each of the pixels including a plurality of photoelectric conversion elements and a floating diffusion configured to accumulate an electric charge from the plurality of photoelectric conversion elements,
   wherein the floating diffusion is shared by at least two or more of the photoelectric conversion elements, and
   wherein one or more of the plurality of photoelectric conversion elements include a transfer gate configured to transfer an electric charge between the photoelectric conversion elements that are adjacent.

What is claimed is:

1. A solid-state imaging device comprising:
a pixel array unit in which pixels are arrayed in a two-dimensional manner, each of the pixels including a plurality of photoelectric conversion elements and a floating diffusion configured to accumulate an electric charge from the plurality of photoelectric conversion elements,
wherein the floating diffusion is shared by at least two or more of the photoelectric conversion elements, and
wherein one or more of the plurality of photoelectric conversion elements include a transfer gate configured to transfer an electric charge between the photoelectric conversion elements that are adjacent.

2. The solid-state imaging device according to claim 1,
wherein, of the plurality of photoelectric conversion elements, the photoelectric conversion elements except the photoelectric conversion elements sharing the floating diffusion include the transfer gate, and
wherein the transfer gate is formed on a separation region that is formed between the photoelectric conversion elements that are adjacent.

3. The solid-state imaging device according to claim 2,
wherein an impurity concentration of the separation region decreases as a cross-section height thereof increases.

4. The solid-state imaging device according to claim 2,
wherein at least part of the transfer gate is implanted in a trench formed in the separation region.

5. The solid-state imaging device according to claim 2,
wherein an impurity concentration of the photoelectric conversion element increases as a distance between the photoelectric conversion element and the floating diffusion shortens.

6. The solid-state imaging device according to claim 2,
wherein the transfer gate is formed for each photoelectric conversion element group, the photoelectric conversion element group being an aggregate of the photoelectric conversion elements.

7. The solid-state imaging device according to claim 6,
wherein a drive signal driving the transfer gate is supplied to the transfer gate for each photoelectric conversion element group depending on an imaging mode.

8. The solid-state imaging device according to claim 6,
wherein a drive signal driving the transfer gate is supplied to the transfer gate for each photoelectric conversion element group depending on an imaging environment.

9. A production method of a solid-state imaging device including a pixel array unit in which pixels are arrayed in a two-dimensional manner, each of the pixels including a plurality of photoelectric conversion elements and a floating diffusion configured to accumulate an electric charge from the plurality of photoelectric conversion elements, the production method comprising:
forming the floating diffusion shared by at least two or more of the photoelectric conversion elements; and
forming a transfer gate configured to transfer an electric charge between the photoelectric conversion elements that are adjacent, for one or more of the plurality of photoelectric conversion elements.

10. An electronic apparatus comprising:
a solid-state imaging device including:
a pixel array unit in which pixels are arrayed in a two-dimensional manner, each of the pixels including a plurality of photoelectric conversion elements and a floating diffusion configured to accumulate an electric charge from the plurality of photoelectric conversion elements,
wherein the floating diffusion is shared by at least two or more of the photoelectric conversion elements, and
wherein one or more of the plurality of photoelectric conversion elements include a transfer gate configured to transfer an electric charge between the photoelectric conversion elements that are adjacent.
